(19) United States
(12) Patent Application Publication
(10) Pub. No.: US 2025/0266294 A1
(43) Pub. Date: Aug. 21, 2025

(54) METHODS FOR DEPOSITING SILICON OXIDE

(71) Applicant: Applied Materials, Inc., Santa Clara, CA (US)

(72) Inventors: Siyao WANG, San Jose, CA (US); Keith Tatseun WONG, Los Gatos, CA (US)

(21) Appl. No.: 19/035,655

(22) Filed: Jan. 23, 2025

Related U.S. Application Data
(60) Provisional application No. 63/554,820, filed on Feb. 16, 2024.
(60) Provisional application No. 63/554,915, filed on Feb. 16, 2024.

(51) Int. Cl. H01L 21/768; H01L 21/02; H01L 21/311

(52) U.S. Cl. CPC H01L 21/76837; H01L 21/02164; H01L 21/02211; H01L 21/02274; H01L 21/0228; H01L 21/31111; H01L 21/31116

(57) ABSTRACT

Embodiments of the present disclosure generally relate to methods for silicon oxide gap filling of trenches and other features. The methods provide bottom-up processes to gapfill features with oxides, such as silicon oxide without voids, seams, or other defects. In one or more embodiments, a method for oxide gap filling is provided and includes providing a workpiece containing features, conducting a deposition-etch cycle to deposit a fill material containing silicon oxide into the features, and repeating the deposition-etch cycle including a PE-ALD process and an etch process to bottom-up fill the features with the fill material. The deposition-etch cycle includes conducting the PE-ALD process to deposit the silicon oxide on the sidewall surfaces and the bottom surfaces. The etch process is conducted to selectively remove the silicon oxide from the sidewall surfaces while maintaining the silicon oxide on the bottom surfaces.

### CROSS-REFERENCE TO RELATED APPLICATIONS

This application claims priority to U.S. Prov. Appl. No. 63/554,820, filed on Feb. 16, 2024, and claims priority to U.S. Prov. Appl. No. 63/554,915, filed on Feb. 16, 2024, which are herein incorporated by reference in their entirety.

### BACKGROUND

### Field

Embodiments of the present disclosure generally relate to depositing oxides, and more specifically, conducting bottom-up silicon oxide gapfill into features.

### Description of the Related Art

Microelectronics, including integrated circuits, are fabricated by processes which produce intricately patterned layers on substrates. As device sizes continue to become smaller, the deposition or formation of materials can affect subsequent process operations. In one such example, one or more materials can be deposited or otherwise formed to fill features (e.g., trenches, holes, etc.) disposed on substrates. As fabrication techniques evolve, there becomes more demand for features with greater aspect ratios increase and reduced critical dimensions. However, the process of properly filling such features become complicated and challenging. For example, the material being deposited into a feature may accumulate near the top and/or sidewalls of the feature and prematurely close-off the opening forming a void and/or a seam within the feature. Such defect in the feature will likely impact subsequent fabrication processes and/or performance of the overall fabricated device.

Processes to deposit or otherwise form oxide within trenches, gaps, and other features are known, such processes typically produce voids, seams, and/or other defects within the oxide of the feature. Flowable chemical vapor deposition (FCVD) has been used to fill features. However, the quality of oxide is often deficient and post treatments (e.g., steam anneal at 550° C.) to enhance the oxide quality leads to germanium diffusion and oxidation due to exceeding thermal budgets of about 400° C.

Therefore, a need exists for improved methods to bottom-up gapfill features with oxide materials.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIGS. 1A-1G depict a series of cross-sectional views of a workpiece at different stages of a method for conducting oxide gap filling, according to one or more embodiments described and discussed herein.

FIG. 2 is a flowchart depicting a method for oxide gap filling, according to one or more embodiments described and discussed herein.

To facilitate understanding, identical reference numerals have been used, where possible, to designate identical elements that are common to the Figures. It is contemplated that elements and features of one or more embodiments may be beneficially incorporated in other embodiments.

### SUMMARY

Embodiments of the present disclosure generally relate to methods for silicon oxide gap filling of trenches and other features. The methods described and discussed herein provide bottom-up processes to gapfill features with oxides, such as silicon oxide. The silicon oxide filled features are fabricated without voids, seams, or other defects. The silicon oxide is deposited or otherwise formed of a high quality oxide. Also, thermal budgets during the methods may be maintained near or below temperatures so to reduce or prohibit germanium diffusion from the substrate or underlayer into the silicon oxide.

In one or more embodiments, a method of oxide gap filling is provided and includes providing a workpiece containing a feature layer disposed on a substrate, where the feature layer contains features formed therein, and each of the features has sidewall surfaces and a bottom surface, and each feature has an aspect ratio of 20 or greater, conducting a deposition-etch cycle to deposit a fill material containing silicon oxide into the features, and repeating the deposition-etch cycle including a plasma-enhanced atomic layer deposition (PE-ALD) process and an etch process to bottom-up fill the features with the fill material. The deposition-etch cycle includes conducting the PE-ALD process to deposit the silicon oxide on the sidewall surfaces and the bottom surfaces, where the PE-ALD process includes applying a bias power to the workpiece and conducting an atomic layer deposition (ALD) cycle for at least 10 times to deposit the silicon oxide. The etch process is conducted to selectively remove the silicon oxide from the sidewall surfaces while maintaining the silicon oxide on the bottom surfaces. In some examples, the etch process may be a dry etch process or a wet etch process.

In some embodiments, a method of oxide gap filling is provided and includes positioning a workpiece containing a feature layer disposed on a substrate within a processing region of a processing chamber, where the feature layer contains features formed therein, and each of the features has sidewall surfaces and a bottom surface, and each feature has an aspect ratio of 20 or greater. The method further includes conducting a PE-ALD process to deposit silicon oxide on the sidewall surfaces and the bottom surfaces, where the PE-ALD process includes applying a bias power to the workpiece and conducting an ALD cycle from about 10 times to about 150 times to deposit the silicon oxide. Then, the method includes conducting an etch process to selectively remove the silicon oxide from the sidewall surfaces while maintaining the silicon oxide on the bottom surfaces. The method also includes repeating the PE-ALD process and the etch process during a deposition-etch cycle to bottom-up fill the features.

In other embodiments, a method of oxide gap filling is provided and includes positioning a workpiece containing a feature layer disposed on a substrate within a processing chamber, where the feature layer contains features formed therein, and each of the features has sidewall surfaces and a bottom surface, and each feature has an aspect ratio of 20 or greater. The method also includes conducting a PE-ALD process to deposit silicon oxide on the sidewall surfaces and the bottom surfaces. The PE-ALD process includes applying a bias power to the workpiece and conducting an ALD cycle from about 10 times to about 150 times to deposit the silicon oxide. Each of the ALD cycles includes exposing the workpiece to a silicon precursor, exposing the workpiece to a purge gas, exposing the workpiece to an oxidizing plasma, and exposing the workpiece to the purge gas. The workpiece is sequentially exposed to the silicon precursor, the purge gas, the oxidizing plasma, and the purge gas. The method further includes conducting an etch process to selectively remove the silicon oxide from the sidewall surfaces while maintaining the silicon oxide on the bottom surfaces, where the etch process is a wet etch process which includes exposing the workpiece to an etch solution to selectively remove the silicon oxide from the sidewall surfaces while maintaining the silicon oxide on the bottom surfaces. The method also includes repeating the PE-ALD process and the etch process during a deposition-etch cycle to bottom-up fill the features. In one or more examples, the etch solution contains hydrofluoric acid.

In some embodiments, a method of oxide gap filling is provided and includes positioning a workpiece containing a feature layer disposed on a substrate within a processing chamber, where the feature layer contains features formed therein, and each of the features has sidewall surfaces and a bottom surface. The method also includes conducting a PE-ALD process to deposit silicon oxide on the sidewall surfaces and the bottom surfaces, where the PE-ALD process includes applying a bias power to the workpiece and conducting an ALD cycle to deposit the silicon oxide. The method further includes conducting an etch process to selectively remove the silicon oxide from the sidewall surfaces while maintaining the silicon oxide on the bottom surfaces. The etch process is a dry etch process which includes exposing the workpiece to a plasma etch to selectively remove the silicon oxide from the sidewall surfaces while maintaining the silicon oxide on the bottom surfaces. Thereafter, the method can include repeating the PE-ALD process and the etch process during a deposition-etch cycle to bottom-up fill the features. In one or more examples, the dry etch process includes generating a capacitively coupled plasma having a power of about 20 watt to about 200 watt. In other examples, the dry etch process includes exposing the workpiece to a plasma formed from a reactive gas containing carbon tetrafluoride, nitrogen trifluoride, hydrogen fluoride, ammonia, or any combination thereof.

### DETAILED DESCRIPTION

Embodiments of the present disclosure generally relate to methods for oxide gap filling of trenches and other features. The methods described and discussed herein provide bottom-up processes to gapfill features with oxides, such as silicon oxide. The silicon oxide filled features are fabricated without voids, seams, or other defects. In one or more examples, the features form shallow trench isolation (STI) structures in microelectronic devices.

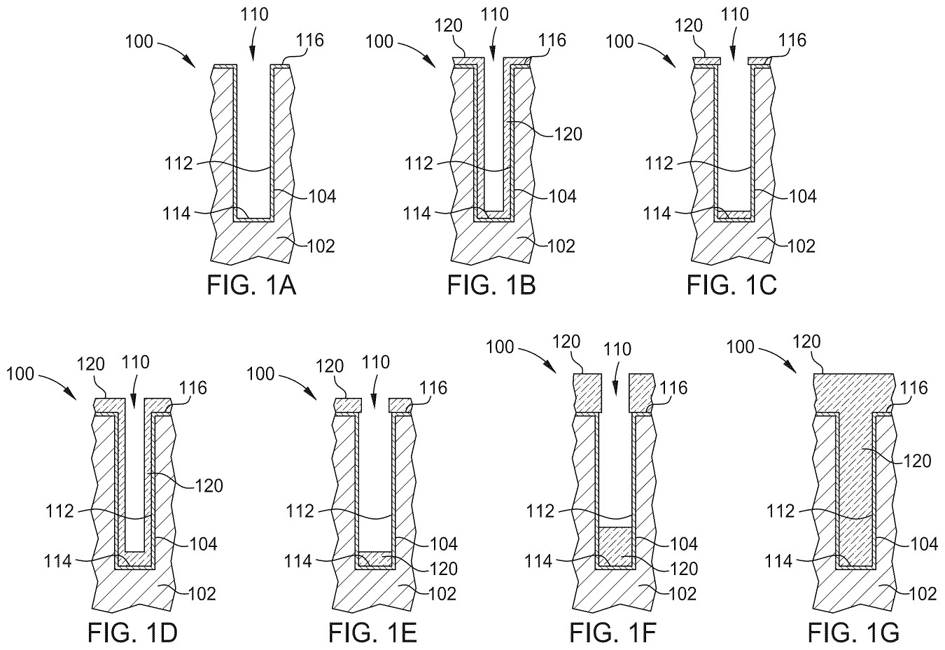

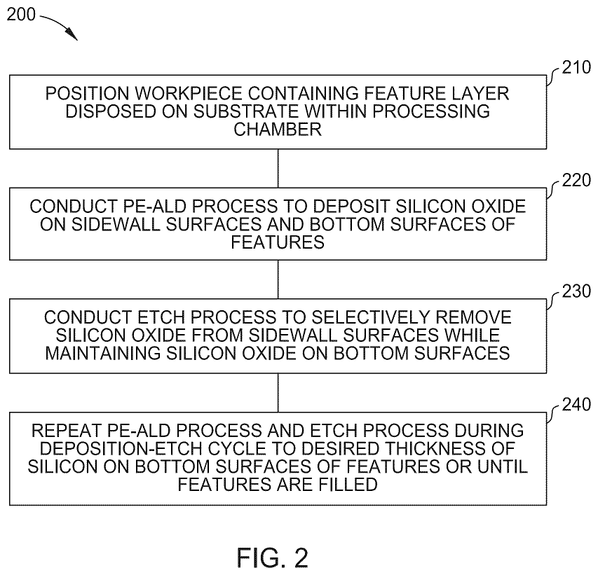

FIGS. 1A-1G depict a series of cross-sectional views of a workpiece 100 at different stages of a method (e.g., method 200 in FIG. 2) for conducting oxide gap filling, according to one or more embodiments described and discussed herein. FIG. 1A depicts the workpiece 100 containing a feature layer 104 disposed on a substrate 102. The substrate 102 and/or the feature layer 104 contains one or more features, such as a plurality of features 110 formed or otherwise defined therein. Each feature 110 may independently extend from an upper surface 116 of the workpiece 100 to a particular depth within the substrate 102 and/or the feature layer 104. The feature layer 104 is optional and/or may be a portion of the substrate 102. In one or more examples, the feature layer 104 is not included on the workpiece 100. In some examples, the workpiece 100 may be the substrate 102. In other examples, the feature layer 104 is included on the workpiece 100. In some examples, the feature layer 104 is included and contains 2, 3 or more films or the same composition or different compositions.

The substrate 102 may be or include any suitable substrate material and the feature layer 104 may be or include any suitable material, which is the same or different than the substrate material. In one or more embodiments, the substrate 102 and/or the feature layer 104 may contain one or more semiconductor materials and/or dopants, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), copper indium gallium selenide (CIGS), other semiconductor materials, dopants thereof, or any combination thereof. Although a few examples of materials from which the substrate 102 and/or the feature layer 104 may be formed are described herein, any material that may serve as a foundation upon which passive and active electronic devices (e.g., memories, transistors, capacitors, inductors, resistors, switches, integrated circuits, amplifiers, optoelectronic devices, or any other electronic devices) may be fabricated is within the spirit and scope of the present disclosure. In one or more examples, the substrate 102 and/or the feature layer 104 may be or contain silicon, a silicon germanium compound, a silicon germanium carbon compound, or any dopant thereof. In one or more examples, the feature layer 104 may be or contain silicon, silicon germanium, dopants thereof, or any combination thereof. In other examples, the feature layer 104 contains a silicon germanium film disposed on a silicon surface.

For exemplary purposes, the Figures illustrate the feature 110 as a single feature, but the substrate 102 and/or the feature layer 104 may contain any number of features or structures and of any geometry. In one or more examples, the plurality of features 110 form a shallow trench isolation (STI) structure. In other examples, the plurality of features 110 may be a deep trench isolation (DTI) structure or a sacrificial patterning structure. Each of the features 110 has sidewall surfaces 112 and a bottom surface 114. The aspect ratio of each feature is determined by the height of the feature 110 divide the width of the feature 110, such as the ratio of the length of sidewall surface 112 to the bottom surface 114. Each feature 110 may have an aspect ratio of about 10, about 20, or greater. In one or more embodiments, the aspect ratio of each feature 110 may be greater than 20, greater than 25, greater than 30, or greater than 40. In other embodiments, the aspect ratio of each feature 110 is in a range from about 20, about 22, about 25, about 28, about 30, about 35, about 40, or about 45 to about 50, about 60, about 70, about 80, about 90, about 100, about 120, about 150, or greater. For example, the aspect ratio of each feature 110 may be in a range from

about 10 to about 150, about 10 to about 120, about 10 to about 100, about 10 to about 80, about 10 to about 50, about 10 to about 40, about 10 to about 30, about 10 to about 25, about 10 to about 20, about 10 to about 15, about 20 to about 150, about 20 to about 120, about 20 to about 100, about 20 to about 80, about 20 to about 50, about 20 to about 40, about 20 to about 30, about 20 to about 25, about 18 to about 20, greater than 20 to about 150, greater than 20 to about 120, greater than 20 to about 100, greater than 20 to about 80, greater than 20 to about 50, greater than 20 to about 40, greater than 20 to about 30, greater than 20 to about 25, greater than 22 to about 100, about 22 to about 100, about 25 to about 150, about 25 to about 120, about 25 to about 100, about 25 to about 80, about 25 to about 50, about 25 to about 40, about 25 to about 30, about 25 to about 25, about 25 to about 20, about 25 to about 15, or about 30 to about 50.

FIG. 2 is a flowchart depicting a process or method 200 for oxide gap filling, according to one or more embodiments described and discussed herein. Other types of features, holes, or voids may be partially or completely filled with oxide by the method 200. The method 200 includes operations 210-240 as further described and discussed below. At operation 210, the workpiece 100 with the features 110 may be provided or otherwise position, as depicted in FIG. 1A. At operation 220, the workpiece 100 is exposed to part of a deposition-etch cycle by conducting a plasma-enhanced atomic layer deposition (PE-ALD) process to deposit the fill material containing the silicon oxide 120 on the sidewall surfaces 112 and the bottom surfaces 114, as depicted in FIG. 1B. In some examples, the PE-ALD process uses a directional oxidizing plasma to selectively treat horizontal surfaces (e.g., the bottom surfaces 114) without or minimally treating vertical surfaces (e.g., the sidewall surfaces 112). As such, the silicon oxide formed on the bottom surfaces 114 has a greater oxygen to silicon (O:Si) atomic ratio than the silicon oxide formed on the sidewall surfaces 112. At operation 230, the workpiece 100 is exposed to another part of the deposition-etch cycle by conducting an etch process (e.g., dry etch or wet etch) to selectively remove the silicon oxide 120 from the sidewall surfaces 112 while maintaining the silicon oxide 120 on the bottom surfaces 114, as depicted in FIG. 1C. Since the silicon oxide formed on the bottom surfaces 114 (and other horizontal surfaces on the workpiece 100) has a greater O:Si atomic ratio than the silicon oxide formed on the sidewall surfaces 112 (and other vertical surfaces on the workpiece 100), the silicon oxide formed on the sidewall surfaces 112 and other horizontal surfaces is etched at a faster or greater rate than the silicon oxide formed on the bottom surfaces 114 and other vertical surfaces. As such, the vertically positioned silicon oxide is substantially or completely etched or otherwise removed while the horizontally positioned silicon oxide substantially or completely remains during the etch process. At operation 240, the deposition-etch cycle (operations 220 and 230) may be repeated to bottom-up fill the features 110 with the silicon oxide 120 and/or a fill material containing the silicon oxide 120. In some examples, the fill material may be or include the silicon oxide 120. In other examples, the fill material and/or the silicon oxide 120 may contain one or more other compounds and/or one or more elements (e.g., carbon, hydrogen, nitrogen, or a combination thereof).

In one or more examples, operations 220 and 230 are performed for a second time. For example, operation 220 is conducted after the first operation 230 to deposit the silicon oxide 120 on the sidewall surfaces 112 and the bottom surfaces 114, as depicted in FIG. 1D. Thereafter, the etch process of operation 230 is again conducted to selectively remove the silicon oxide 120 from the sidewall surfaces 112 while maintaining the silicon oxide 120 on the bottom surfaces 114, as depicted in FIG. 1E. In one or more embodiments, the deposition-etch cycle (operations 220 and 230) may be repeated one or multiple more time to partially fill the features, as depicted in FIG. 1F, and/or to continue filling and completely bottom-up fill the features 110, as depicted in FIG. 1G.

In one or more embodiments, a method of oxide gap filling is provided and includes positioning the workpiece 100 containing the feature layer 104 disposed on the substrate 102 within the processing region of a processing chamber (e.g., ALD chamber), at operation 210. The feature layer 104 contains the plurality of features 110 formed therein, and each of the features 110 has sidewall surfaces 112 and a bottom surface 114, and each feature 110 has an aspect ratio of 10, 20, or greater. The method further includes conducting the PE-ALD process to deposit silicon oxide 120 on the sidewall surfaces 112 and the bottom surfaces 114, at operation 220. The PE-ALD process includes applying a bias power to the workpiece 100 and conducting an atomic layer deposition (ALD) cycle from about 10 times to about 150 times to deposit the silicon oxide 120. In one or more examples, the oxidizing plasma in the ALD cycle may have a bias of 350 KHz, 2 MHz, 13 MHz, or other frequencies. The method also includes conducting an etch process to selectively remove the silicon oxide 120 from the sidewall surfaces 112 while maintaining the silicon oxide 120 on the bottom surfaces 114, at operation 230. The method also includes repeating the PE-ALD process and the etch process during a deposition-etch cycle to bottom-up fill the features 110, at operation 240.

At operation 220 of the method 200, the silicon oxide 120 is deposited by PE-ALD on the sidewall surfaces 112 and the bottom surfaces 114, as depicted in FIGS. 1B and 1D. Each of the ALD cycles includes exposing the workpiece 100 to one or more silicon precursors, exposing the workpiece 100 to one or more purge gases, exposing the workpiece 100 to one or more oxidizing plasmas, and exposing the workpiece 100 to the purge gas. The workpiece 100 is sequentially exposed to the silicon precursor, the purge gas, the oxidizing plasma, and the purge gas during the ALD cycle in order to deposit the fill material containing silicon oxide. The ALD cycle may be repeated as many times as desired to deposit the fill material containing the silicon oxide to the desired thickness during each of the deposition-etch cycles. In one or more embodiments, the plasma is powered on while generating and exposing the workpiece 100 to the oxidizing plasma, and the plasma is powered off while exposing the workpiece 100 to the silicon precursor and the purge gas during the ALD cycle.

The oxidizing plasma has a flow path or directional path which is perpendicular or substantially perpendicular relative an upper surface 116 of the workpiece 100. The oxidizing plasma reacts with the silicon precursor to form the silicon oxide on the exposed surfaces of the workpiece 100. The PE-ALD process includes exposing the workpiece 100 to the oxidizing plasma to form the silicon oxide, such that the bottom surfaces 114 or other horizontal surfaces of the features 110 are exposed to a greater concentration of the oxidizing plasma than the sidewall surfaces 112 or other vertical surfaces of the features 110. The silicon oxide deposited or otherwise formed on the bottom surfaces 114, other horizontal surfaces of the features 110, and/or other horizontal surfaces on the workpiece 100 has a greater O:Si atomic ratio than the silicon oxide deposited or otherwise formed on the sidewall surfaces 112, other vertical surfaces of the features 110, and/or other vertical surfaces on the workpiece 110. In some examples, the silicon oxide disposed on the bottom surfaces 114 can have an O:Si atomic ratio of 2, while the silicon oxide disposed on the sidewall surfaces 112 can have an O:Si atomic ratio of less than 2. In other examples, the silicon oxide disposed on the bottom surfaces 114 can have an O:Si atomic ratio of less than 2, while the silicon oxide disposed on the sidewall surfaces 112 can have an O:Si atomic ratio of less than the silicon oxide disposed on the bottom surfaces 114. In some examples, the silicon oxide disposed on the sidewall surfaces 112 can have a greater carbon concentration than the silicon oxide disposed on the bottom surfaces 114.

In each cycle of operation 220, the ALD cycle may be conducted about 5 times, about 8 times, about 10 times, greater than 10 times, about 15 times, about 20 times, about 25 times, about 30 times, about 35 times, about 40 times, about 45 times, about 50 times, about 55 times, about 60 times, about 65 times, about 70 times, or about 75 times to about 80 times, about 85 times, about 90 times, about 95 times, about 100 times, about 110 times, about 120 times, about 130 times, about 140 times, about 150 times, about 180 times, about 200 times, or more. For example, the ALD cycle may be conducted in a range from about 10 times to about 200 times, about 10 times to about 180 times, about 10 times to about 150 times, about 10 times to about 120 times, about 10 times to about 100 times, about 10 times to about 80 times, about 10 times to about 70 times, about 10 times to about 60 times, about 10 times to about 50 times, about 10 times to about 40 times, about 10 times to about 30 times, about 10 times to about 25 times, about 10 times to about 20 times, about 10 times to about 15 times, greater than 10 times to about 150 times, about 20 times to about 100 times, about 40 times to about 90 times, about 60 times to about 85 times, about 70 times to about 85 times, about 75 times to about 85 times, or about 70 times to about 80 times to deposit the silicon oxide during each deposition-etch cycle.

The workpiece 100 and/or the processing region is heated or maintained at a process temperature in a range from about 300° C. to about 600° C. during the PE-ALD process. In some examples, the process temperature may be in a range from about 350° C. to about 550° C. during the PE-ALD process. In other examples, the process temperature may be at or less than 500° C., such as at or less than 400° C. during the PE-ALD process. The processing region may be maintained at a pressure in a range from about 0.1 Torr to about 10 Torr or about 0.5 Torr to about 4 Torr during the PE-ALD process.

The silicon precursor may be or include bis(diethylamino)silane (BDEAS) {((CH₃CH₂)₂N)₂SiH₂}; di(iso-propylamino)silane (DIPAS) {(ⁱPrHN)₂SiH₂}; bis(tert-butylamino)silane (BTBAS) {(ⁱBuNN)₂SiH₂}; di(sec-butylamino)silane (DSBAS) {(^{s}BuHN)₂SiH₂}; mono(disec-butylamino)silane (MDSBAS) {(^{s}Bu₂N)SiH₃}; bis(diisopropylamino)disilane (BDIPADS) {((ⁱPr₂N)SiH₂)₂}; bis(dimethylamino)dimethylsilane (BDMADMS) {((CH₃)₂N)₂Si(CH₃)₂}; tris(dimethylamino)silane (TDMAS) {((CH₃)₂N)₃SiH}, or any combination thereof. In some examples, the silicon precursor can include one or more carrier gases. Exemplary carrier gas may be or include nitrogen (N₂), argon, helium, or any combination thereof.

In some examples, the silicon precursor may be introduced in the processing chamber, the processing region, or exposed to the workpiece at a flowrate within a range from about 10 milligram/minute (mgm), about 20 mgm, about 30 mgm, about 40 mgm, about 50 mgm, about 60 mgm, about 80 mgm, about 100 mgm, about 120 mgm, about 135 mgm, or about 150 mgm to about 180 mgm, about 200 mgm, about 220 mgm, about 250 mgm, about 280 mgm, about 300 mgm, about 350 mgm, about 400 mgm, about 450 mgm, about 500 mgm, or greater. For example, the silicon precursor may be introduced in the processing chamber, the processing region, or exposed to the workpiece at a flowrate within a range from about 10 mgm to about 500 mgm, about 10 mgm to about 400 mgm, about 10 mgm to about 300 mgm, about 10 mgm to about 250 mgm, about 10 mgm to about 200 mgm, about 10 mgm to about 150 mgm, about 10 mgm to about 120 mgm, about 10 mgm to about 100 mgm, about 10 mgm to about 80 mgm, about 10 mgm to about 50 mgm, about 10 mgm to about 30 mgm, about 10 mgm to about 20 mgm, about 50 mgm to about 500 mgm, about 50 mgm to about 400 mgm, about 50 mgm to about 300 mgm, about 50 mgm to about 250 mgm, about 50 mgm to about 200 mgm, about 50 mgm to about 150 mgm, about 50 mgm to about 120 mgm, about 50 mgm to about 100 mgm, about 50 mgm to about 80 mgm, about 100 mgm to about 500 mgm, about 100 mgm to about 400 mgm, about 100 mgm to about 300 mgm, about 100 mgm to about 250 mgm, about 100 mgm to about 200 mgm, about 100 mgm to about 150 mgm, or about 100 mgm to about 120 mgm. In other examples, the silicon precursor may be introduced in the processing chamber, the processing region, or exposed to the workpiece at a flowrate within a range from about 10 mgm to about 500 mgm, about 30 mgm to about 300 mgm, about 50 mgm to about 200 mgm, or about 100 mgm to about 180 mgm.

In other embodiments, the silicon precursor may be introduced in the processing chamber, the processing region, or exposed to the workpiece with a pulse rate in a range from about 0.05 seconds (s), about 0.1 s, about 0.2 s, about 0.3 s, about 0.4 s, or about 0.5 s to about 0.6 s, about 0.7 s, about 0.8 s, about 0.9 s, about 1.0 s, about 1.2 s, about 1.5 s, about 2 s, or longer during the PE-ALD cycle. In one or more examples, the silicon precursor may be introduced in the processing chamber, the processing region, or exposed to the workpiece with a pulse rate in a range from about 0.05 s to about 2 s, about 0.05 s to about 1.8 s, about 0.05 s to about 1.5 s, about 0.05 s to about 1.2 s, about 0.05 s to about 1 s, about 0.05 s to about 0.8 s, about 0.05 s to about 0.5 s, about 0.05 s to about 0.1 s, about 0.1 s to about 2 s, about 0.1 s to about 1.8 s, about 0.1 s to about 1.5 s, about 0.1 s to about 1.2 s, about 0.1 s to about 1 s, about 0.1 s to about 0.8 s, about 0.1 s to about 0.5 s, about 0.5 s to about 2 s, about 0.5 s to about 1.8 s, about 0.5 s to about 1.5 s, about 0.5 s to about 1.2 s, about 0.5 s to about 1 s, or about 0.5 s to about 0.8 s.

The oxidizing plasma may be or include atomic oxygen, oxygen gas (O₂), ozone, water, nitrous oxide, or any combination thereof. The oxidizing plasma has a power of about 50 watt to about 1,000 watt, such as about 100 watt to about 600 watt. In one or more examples, the oxidizing plasma may have a bias of 350 KHz, 2 MHz, 13 MHz, or other frequencies. In one or more examples, the oxidizing plasma is formed from oxygen gas (O₂). The oxygen gas, the oxygen precursor, and/or other oxygen containing compounds may be introduced in the processing chamber, the processing region, or exposed to the workpiece at a flowrate within a range from about 50 sccm to about 1,000 sccm, about 150 sccm to about 750 sccm, or about 250 sccm to about 500 sccm.

In other embodiments, the oxygen gas, the oxygen precursor, and/or other oxygen containing compounds may be introduced in the processing chamber, the processing region, or exposed to the workpiece with a pulse rate in a range from about 0.5 s, about 0.8 s, about 1 s, about 1.2 s, about 1.4 s, or about 1.5 s to about 1.6 s, about 1.8 s, about 2 s, about 2.2 s, about 2.5 s, about 2.8 s, about 3 s, about 4 s, about 5 s, or longer during the PE-ALD cycle. In one or more examples, the oxygen gas, the oxygen precursor, and/or other oxygen containing compounds may be introduced in the processing chamber, the processing region, or exposed to the workpiece with a pulse rate in a range from about 1 s to about 3 s.

The purge gas may be or include nitrogen (N₂), argon, helium, or any combination thereof. The purge gas may be introduced in the processing chamber, the processing region, or exposed to the workpiece at a flowrate within a range from about 50 sccm to about 1,000 sccm, about 150 sccm to about 750 sccm, or about 250 sccm to about 500 sccm.

In other embodiments, the purge gas may be introduced in the processing chamber, the processing region, or exposed to the workpiece with a pulse rate in a range from about 0.5 s, about 0.8 s, about 1 s, about 1.2 s, about 1.4 s, or about 1.5 s to about 1.6 s, about 1.8 s, about 2 s, about 2.2 s, about 2.5 s, about 2.8 s, about 3 s, about 4 s, about 5 s, or longer during the PE-ALD cycle. In one or more examples, the purge gas may be introduced in the processing chamber, the processing region, or exposed to the workpiece with a pulse rate in a range from about 1 s to about 3 s.

At operation 230 of the method 200, workpiece 100 is exposed to an etch process (e.g., a dry etch process or a wet etch process) to selectively remove the silicon oxide 120 from the sidewall surfaces 112 while maintaining the silicon oxide 120 on the bottom surfaces 114, as depicted in FIGS. 1C and 1E-1F.

In one or more embodiments, the etch process may be or include a wet etch process. The workpiece 100 is removed from the deposition chamber (e.g., ALD chamber) and transferred in to chamber suitable for a wet etch process, such as a wet etch chamber. The wet etch process which includes exposing the workpiece 100 to an etch solution to selectively remove the silicon oxide 120 from the sidewall surfaces 112 while maintaining the silicon oxide 120 on the bottom surfaces 114. In some examples, the etch solution contains water and hydrofluoric acid. For example, the etch solution may be or contain a dilute hydrofluoric acid (dHF) solution containing about 100:1 water to hydrogen fluoride. In other examples, the ratio of water to HF may be in a range from about 500:1, about 400:1, about 350:1, about 300:1, about 250:1, about 200:1, about 180:1, about 150:1, about 120:1, about 100:1, about 80:1, about 60:1, about 50:1, about 40:1, about 20:1, or about 10:1.

The workpiece 100 may be exposed to the etch solution heated, cooled, or otherwise maintained at a temperature in a range from about 10° C., about 20° C., about 22° C., about 25° C., about 28° C., or about 30° C. to about 32° C., about 35° C., about 40° C., about 50° C., about 65° C., about 80° C., or about 100° C. during the wet etch process. In one or more examples, the workpiece 100 may be exposed to the etch solution heated, cooled, or otherwise maintained at a temperature in a range from about 10° C. to about 50° C., about 20° C. to about 35° C., about 22° C. to about 30° C., or about 25° C. to about 28° C. during the wet etch process.

The workpiece 100 may be exposed to the etch solution for about 1 second (s), about 5 s, about 10 s, about 15 s, about 20 s, about 30 s, or about 45 s to about 1 minute (min), about 1.5 min, about 2 min, about 3 min, about 4 min, about 5 min, or about 10 min. In some examples, the workpiece 100 may be exposed to the etch solution containing dHF of about 100:1 for about 5 s to about 1 min.

In other embodiments, the etch process may be or include a dry etch process. In one or more examples, the workpiece 100 is removed from the deposition chamber (e.g., ALD chamber) and transferred in to chamber suitable for a dry etch process, such as a plasma chamber or a dry etch chamber. In other examples, the workpiece 100 is maintained in the deposition chamber, such as a PE-ALD chamber. The dry etch process includes exposing the workpiece 100 to a plasma etch to selectively remove the silicon oxide 120 from the sidewall surfaces 112 while maintaining the silicon oxide 120 on the bottom surfaces 114. The dry etch process includes include exposing the workpiece 100 to a plasma generated by one or more types of plasma sources and/or processes, such as a remote plasma source (RPS), a remote inductively coupled plasma (ICP) source, a remote capacitively coupled plasma (CCP) source, an ICP with low source power and no bias, or any combination thereof.

In one or more embodiments, the workpiece 100 and/or the processing region is heated or maintained at a process temperature in a range from about 100° C. to about 600° C., about 200° C. to about 600° C., or about 300° C. to about 600° C. during the dry etch process. In some examples, the process temperature during the dry etch process may be in a range from about 350° C. to about 550° C. In other examples, the process temperature may be at or less than 500° C., such as at or less than 400° C. during the dry etch process. In other embodiments, the workpiece 100 and/or the processing region is heated or maintained at a process temperature of less than 100° C. during the dry etch process. In some examples, the process temperature during the dry etch process may be less than 90° C., less than 80° C., less than 60° C. or less than 50° C. In other examples, the process temperature may be in a range from about 0° C. to about 50° C., about 10° C. to about 50° C., about 20° C. to about 50° C., about 22° C. to about 50° C., about 25° C. to about 50° C., about 28° C. to about 50° C., about 30° C. to about 50° C., about 35° C. to about 50° C., or about 40° C. to about 50° C. during the dry etch process. The processing region may be maintained at a pressure in a range from about 0.1 Torr to about 10 Torr, about 0.5 Torr to about 4 Torr, or about 0.8 Torr to about 3 Torr during the dry etch process.

The dry etch process includes exposing the workpiece 100 to a plasma formed from a reactive gas. The reactive gas may be or include carbon tetrafluoride, difluoromethane (CH₂F₂), hexafluorobutadiene (C₄F₆), octafluorocyclobutane (C₄H₈), nitrogen trifluoride, hydrogen fluoride, fluorine (F₂), ammonia, one or more carrier gases (e.g., argon, helium, nitrogen (N₂), or mixtures thereof), or any combination thereof. In one or more examples, the plasma is formed or otherwise produced from a reactive gas containing carbon tetrafluoride. In other examples, the plasma is formed or otherwise produced from a reactive gas containing carbon tetrafluoride and nitrogen trifluoride. In some examples, the dry etch process includes exposing the workpiece to a plasma formed from a reactive gas containing nitrogen trifluoride and ammonia.

The reactive gas and/or each of the components of the reactive gas may independently be introduced in the processing chamber, the processing region, or exposed to the workpiece at a flowrate within a range from about 10 sccm to about 500 sccm, about 10 sccm to about 350 sccm, or about 10 sccm to about 200 sccm. In one or more examples, each of the carbon tetrafluoride and the nitrogen trifluoride can independently have a flowrate of about 10 sccm to about 200 sccm.

In or more embodiments, a capacitively coupled plasma may be generated and used during the dry etch process. In some examples, the dry etch process includes generating the plasma having a power of about 20 watt to about 200 watt, such as about 50 watt to about 150 watt and having a bias of 13 MHz.

The workpiece 100 may be exposed to the reactive gas and the plasma for about 1 s, about 5 s, about 10 s, about 15 s, about 20 s, about 30 s, or about 45 s to about 1 min, about 1.5 min, about 2 min, about 3 min, about 4 min, about 5 min, or about 10 min during the dry etch process. In one or more examples, the workpiece 100 may be exposed to the reactive gas and the plasma for about 5 s to about 60 s, about 10 s to about 60 s, about 20 s to about 60 s, about 5 s to about 30 s, about 10 s to about 30 s, or about 20 s to about 30 s.

At operation 240 of the method 200, in one or more embodiments, the deposition-etch cycle (operations 220 and 230) may be performed a single time and then ceased, such that method 200 is complete. In other embodiments, the deposition-etch cycle is repeated, such that the operations 220 and 230 is performed 2, 3, or more times to bottom-up fill the features 110 with the silicon oxide 120 and/or a fill material containing the silicon oxide 120. In one or more examples, the deposition-etch cycle is performed 2 times, 3 times, 4 times, 5 times, 6 times, or 7 times to 8 times, 9 times, 10 times, about 12 times, about 14 times, about 15 times, about 16 times, about 18 times, about 20 times, or more times. For example, the deposition-etch cycle may be performed from 2 times to about 20 times, from 3 times to about 20 times, from 4 times to about 20 times, about 3 times to about 10 times, about 3 times to about 10 times, about 4 times to about 10 times, about 2 times to about 8 times, about 3 times to about 8 times, about 4 times to about 8 times, about 5 times to about 8 times, or about 6 times to about 8 times.

In one or more embodiments, a method of oxide gap filling is provided and includes providing or positioning a workpiece containing a feature layer disposed on a substrate, where the feature layer contains features formed therein, and each of the features has sidewall surfaces and a bottom surface, and each feature has an aspect ratio of 20 or greater. The method also includes conducting a PE-ALD process to deposit silicon oxide on the sidewall surfaces and the bottom surfaces. The PE-ALD process includes applying a bias power to the workpiece and conducting an ALD cycle from about 10 times to about 150 times to deposit the silicon oxide. Each of the ALD cycles includes exposing the workpiece to a silicon precursor, exposing the workpiece to a purge gas, exposing the workpiece to an oxidizing plasma, and exposing the workpiece to the purge gas. The workpiece is sequentially exposed to the silicon precursor, the purge gas, the oxidizing plasma, and the purge gas. The method further includes conducting an etch process to selectively remove the silicon oxide from the sidewall surfaces while maintaining the silicon oxide on the bottom surfaces, where the etch process is a wet etch process which includes exposing the workpiece to an etch solution to selectively remove the silicon oxide from the sidewall surfaces while maintaining the silicon oxide on the bottom surfaces. The method also includes repeating the PE-ALD process and the etch process during a deposition-etch cycle to bottom-up fill the features. In one or more examples, the etch solution contains hydrofluoric acid.

In other embodiments, a method of oxide gap filling is provided and includes providing or positioning a workpiece containing a feature layer disposed on a substrate, where the feature layer contains features formed therein, and each of the features has sidewall surfaces and a bottom surface. The method also includes conducting a PE-ALD process to deposit silicon oxide on the sidewall surfaces and the bottom surfaces, where the PE-ALD process includes applying a bias power to the workpiece and conducting an ALD cycle to deposit the silicon oxide. The method further includes conducting an etch process to selectively remove the silicon oxide from the sidewall surfaces while maintaining the silicon oxide on the bottom surfaces. The etch process is a dry etch process which includes exposing the workpiece to a plasma etch to selectively remove the silicon oxide from the sidewall surfaces while maintaining the silicon oxide on the bottom surfaces. Thereafter, the method can include repeating the PE-ALD process and the etch process during a deposition-etch cycle to bottom-up fill the features. In one or more examples, the dry etch process includes generating a capacitively coupled plasma having a power of about 20 watt to about 200 watt. In other examples, the dry etch process includes exposing the workpiece to a plasma formed from a reactive gas containing carbon tetrafluoride, nitrogen trifluoride, hydrogen fluoride, ammonia, or any combination thereof. In some examples, the dry etch process includes exposing the workpiece to a plasma formed from a reactive gas containing nitrogen trifluoride and ammonia.

Most traditional atomic layer deposition (ALD) chambers may be used as the processing chamber suitable for performing the vapor deposition processes described and discussed herein. An example of a tool or system that may benefit from the vapor deposition processes described and discussed herein is the Centura© system or Endura© system with an iSprint™ ALD/CVD SSW chamber, commercially available from Applied Materials, Inc. In addition, wet etch process chambers, dry etch process chambers, and plasma process chambers, which may be used in the etch processes described and discussed herein, are all commercially available from Applied Materials, Inc.

Embodiments of the present disclosure further relate to any one or more of the following Clauses 1-33:

Clause 1. A method of oxide gap filling, comprising: providing a workpiece containing a feature layer disposed on a substrate, wherein the feature layer comprises features formed therein, and each of the features has sidewall surfaces and a bottom surface, and optionally each feature has an aspect ratio of 20 or greater; conducting a deposition-etch cycle to deposit a fill material comprising silicon oxide into the features, wherein the deposition-etch cycle comprises: conducting a plasma-enhanced atomic layer deposition (PE-ALD) process to deposit the silicon oxide on the sidewall surfaces and the bottom surfaces, wherein the PE-ALD process comprises applying a bias power to the workpiece and optionally conducting an atomic layer deposition (ALD) cycle for at least 10 times to deposit the silicon oxide; and conducting an etch process to selectively remove the silicon oxide from the sidewall surfaces while maintaining the silicon oxide on the bottom surfaces; and repeating the deposition-etch cycle including the PE-ALD process and the etch process to bottom-up fill the features with the fill material.

Clause 2. A method of oxide gap filling, comprising: positioning a workpiece containing a feature layer disposed on a substrate within a processing region of a processing chamber, wherein the feature layer comprises features formed therein, and each of the features has sidewall surfaces and a bottom surface, and optionally each feature has an aspect ratio of 20 or greater; conducting a PE-ALD process to deposit silicon oxide on the sidewall surfaces and the bottom surfaces, wherein the PE-ALD process comprises applying a bias power to the workpiece and optionally conducting an ALD cycle from about 10 times to about 150 times to deposit the silicon oxide; conducting an etch process to selectively remove the silicon oxide from the sidewall surfaces while maintaining the silicon oxide on the bottom surfaces; and repeating the PE-ALD process and the etch process during a deposition-etch cycle to bottom-up fill the features.

Clause 3. A method of oxide gap filling, comprising: providing a workpiece containing a feature layer disposed on a substrate, wherein the feature layer comprises features formed therein, and each of the features has sidewall surfaces and a bottom surface, and optionally each feature has an aspect ratio of 20 or greater; conducting a deposition-etch cycle to deposit a fill material comprising silicon oxide into the features, wherein the deposition-etch cycle comprises: conducting a PE-ALD process to deposit the silicon oxide on the sidewall surfaces and the bottom surfaces, wherein the PE-ALD process comprises applying a bias power to the workpiece and optionally conducting an ALD cycle for at least 10 times to deposit the silicon oxide; and conducting an etch process to selectively remove the silicon oxide from the sidewall surfaces while maintaining the silicon oxide on the bottom surfaces, wherein the etch process is a wet etch process which comprises exposing the workpiece to an etch solution to selectively remove the silicon oxide from the sidewall surfaces while maintaining the silicon oxide on the bottom surfaces; and repeating the deposition-etch cycle including the PE-ALD process and the etch process to bottom-up fill the features with the fill material.

Clause 4. A method of oxide gap filling, comprising: positioning a workpiece containing a feature layer disposed on a substrate within a processing chamber, wherein the feature layer comprises features formed therein, and each of the features has sidewall surfaces and a bottom surface, and optionally each feature has an aspect ratio of 20 or greater; conducting a PE-ALD process to deposit silicon oxide on the sidewall surfaces and the bottom surfaces, wherein the PE-ALD process comprises applying a bias power to the workpiece and optionally conducting an ALD cycle from about 10 times to about 150 times to deposit the silicon oxide, and wherein each of the ALD cycles comprises: exposing the workpiece to a silicon precursor; exposing the workpiece to a purge gas; exposing the workpiece to an oxidizing plasma; and exposing the workpiece to the purge gas; wherein the workpiece is sequentially exposed to the silicon precursor, the purge gas, the oxidizing plasma, and the purge gas; conducting an etch process to selectively remove the silicon oxide from the sidewall surfaces while maintaining the silicon oxide on the bottom surfaces, wherein the etch process is a wet etch process which comprises exposing the workpiece to an etch solution to selectively remove the silicon oxide from the sidewall surfaces while maintaining the silicon oxide on the bottom surfaces; and repeating the PE-ALD process and the etch process during a deposition-etch cycle to bottom-up fill the features.

Clause 5. A method of oxide gap filling, comprising: providing a workpiece containing a feature layer disposed on a substrate, wherein the feature layer comprises features formed therein, and each of the features has sidewall surfaces and a bottom surface, and optionally each feature has an aspect ratio of 20 or greater; conducting a deposition-etch cycle to deposit a fill material comprising silicon oxide into the features, wherein the deposition-etch cycle comprises: conducting a PE-ALD process to deposit the silicon oxide on the sidewall surfaces and the bottom surfaces, wherein the PE-ALD process comprises applying a bias power to the workpiece and optionally conducting an ALD cycle for at least 10 times to deposit the silicon oxide; and conducting an etch process to selectively remove the silicon oxide from the sidewall surfaces while maintaining the silicon oxide on the bottom surfaces, wherein the etch process is a dry etch process which comprises exposing the workpiece to a plasma etch to selectively remove the silicon oxide from the sidewall surfaces while maintaining the silicon oxide on the bottom surfaces; and repeating the deposition-etch cycle including the PE-ALD process and the etch process to bottom-up fill the features with the fill material.

Clause 6. A method of oxide gap filling, comprising: positioning a workpiece containing a feature layer disposed on a substrate within a processing chamber, wherein the feature layer comprises features formed therein, and each of the features has sidewall surfaces and a bottom surface, and optionally each feature has an aspect ratio of 20 or greater; conducting a PE-ALD process to deposit silicon oxide on the sidewall surfaces and the bottom surfaces, wherein the PE-ALD process comprises applying a bias power to the workpiece and optionally conducting an ALD cycle from about 10 times to about 150 times to deposit the silicon oxide, and wherein each of the ALD cycles comprises: exposing the workpiece to a silicon precursor; exposing the workpiece to a purge gas; exposing the workpiece to an oxidizing plasma; and exposing the workpiece to the purge gas; wherein the workpiece is sequentially exposed to the silicon precursor, the purge gas, the oxidizing plasma, and the purge gas; conducting an etch process to selectively remove the silicon oxide from the sidewall surfaces while maintaining the silicon oxide on the bottom surfaces, wherein the etch process is a dry etch process which comprises exposing the workpiece to a plasma etch to selectively remove the silicon oxide from the sidewall surfaces while maintaining the silicon oxide on the bottom surfaces; and repeating the PE-ALD process and the etch process during a deposition-etch cycle to bottom-up fill the features.

Clause 7. The method according to any one of Clauses 1-6, wherein the deposition-etch cycle is performed in a range from 3 times to about 20 times.

Clause 8. The method according to any one of Clauses 1-7, wherein the ALD cycle is performed in a range from about 20 times to about 100 times to deposit the silicon oxide during each deposition-etch cycle.

Clause 9. The method according to any one of Clauses 1-8, wherein each of the ALD cycles comprises: exposing the workpiece to a silicon precursor; exposing the workpiece to a purge gas; exposing the workpiece to an oxidizing plasma; and exposing the workpiece to the purge gas; wherein the workpiece is sequentially exposed to the silicon precursor, the purge gas, the oxidizing plasma, and the purge gas.

Clause 10. The method according to any one of Clauses 1-9, wherein the silicon precursor comprises: bis(diethylamino)silane (BDEAS) {((CH₃CH₂)₂N)₂SiH₂}; di(iso-propylamino)silane (DIPAS) {(ⁱPrHN)₂SiH₂}; bis(tert-butylamino)silane (BTBAS) {(ⁱBuNN)₂SiH₂}; di(sec-butylamino)silane (DSBAS) {(^{s}BuHN)₂SiH₂}; mono(disec-butylamino)silane (MDSBAS) {(^{s}Bu₂N)SiH₃}; bis(diisopropylamino)disilane (BDIPADS) {((ⁱPr₂N)SiH₂)₂}; bis(dimethylamino)dimethylsilane (BDMADMS) {((CH₃)₂N)₂Si(CH₃)₂}; tris(dimethylamino)silane (TDMAS) {((CH₃)₂N)₃SiH}, or any combination thereof.

Clause 11. The method according to any one of Clauses 1-10, wherein the silicon precursor is introduced at a flowrate within a range from about 10 milligram/minute (mgm) to about 500 mgm.

Clause 12. The method according to any one of Clauses 1-11, wherein the oxidizing plasma comprises atomic oxygen, oxygen gas (O₂), ozone, or any combination thereof.

Clause 13. The method according to any one of Clauses 1-12, wherein the oxidizing plasma is formed from oxygen gas (O₂), and wherein the oxygen gas is introduced at a flowrate within a range from about 50 sccm to about 1,000 sccm.

Clause 14. The method according to any one of Clauses 1-12, wherein the purge gas comprises nitrogen (N₂), argon, helium, or any combination thereof.

Clause 15. The method according to any one of Clauses 1-14, wherein the workpiece and/or the processing region is heated or maintained at temperature in a range from about 300° C. to about 600° C. during the PE-ALD process.

Clause 16. The method according to any one of Clauses 1-15, wherein the processing region is maintained at a pressure in a range from about 0.1 Torr to about 10 Torr during the PE-ALD process.

Clause 17. The method according to any one of Clauses 1-16, wherein the oxidizing plasma has a power of about 50 watt to about 1,000 watt.

Clause 18. The method according to any one of Clauses 1-17, wherein the etch process is a wet etch process which comprises exposing the workpiece to an etch solution to selectively remove the silicon oxide from the sidewall surfaces while maintaining the silicon oxide on the bottom surfaces.

Clause 19. The method according to any one of Clauses 1-18, wherein the etch solution comprises hydrofluoric acid.

Clause 20. The method according to any one of Clauses 1-19, wherein the etch process is a dry etch process which comprises exposing the workpiece to a plasma etch to selectively remove the silicon oxide from the sidewall surfaces while maintaining the silicon oxide on the bottom surfaces.

Clause 21. The method according to any one of Clauses 1-20, wherein the dry etch process comprises generating a capacitively coupled plasma having a power of about 20 watt to about 200 watt.

Clause 22. The method according to any one of Clauses 1-21, wherein the dry etch process comprises exposing the workpiece to a plasma formed from a reactive gas comprising carbon tetrafluoride, nitrogen trifluoride, hydrogen fluoride, ammonia, or any combination thereof.

Clause 23. The method according to any one of Clauses 1-22, wherein the reactive gas is introduced at a flowrate within a range from about 10 sccm to about 500 sccm.

Clause 24. The method according to any one of Clauses 1-23, wherein the workpiece and/or the processing region is heated or maintained at temperature in a range from about 300° C. to about 600° C. during the dry etch process.

Clause 25. The method according to any one of Clauses 1-24, wherein the processing region is maintained at a pressure in a range from about 0.1 Torr to about 10 Torr during the dry etch process.

Clause 26. The method according to any one of Clauses 1-25, wherein the aspect ratio of each feature is in a range from about 22 to about 100.

Clause 27. The method according to any one of Clauses 1-26, wherein the plurality of features form a shallow trench isolation (STI) structure or feature, a deep trench isolation (DTI) structure or feature, or a sacrificial patterning structure or feature.

Clause 28. The method according to any one of Clauses 1-27, wherein the feature layer comprises silicon, silicon germanium, dopants thereof, or any combination thereof.

Clause 29. The method according to any one of Clauses 1-28, wherein the feature layer comprises a silicon germanium film disposed on a silicon surface.

Clause 30. The method according to any one of Clauses 1-29, wherein the silicon oxide formed on the bottom surfaces of the features has a greater O:Si atomic ratio than the silicon oxide formed on the sidewall surfaces of the features.

Clause 31. The method according to any one of Clauses 1-30, wherein the silicon oxide formed on the sidewall surfaces of the features has a greater carbon concentration than the silicon oxide formed on the bottom surfaces of the features

Clause 32. The method according to any one of Clauses 1-31, wherein the PE-ALD process further comprises exposing the workpiece to an oxidizing plasma to form the silicon oxide, and wherein the bottom surfaces of the features are exposed to a greater concentration of the oxidizing plasma than the sidewall surfaces of the features.

Clause 33. The method according to any one of Clauses 1-32, wherein the oxidizing plasma has a flow path which is perpendicular or substantially perpendicular relative an upper surface of the workpiece.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated. As used herein, the term “about” refers to a +/−10% variation from the nominal value. It is to be understood that such a variation can be included in any value provided herein.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. A method, comprising:
conducting a deposition-etch cycle to deposit a fill material comprising silicon oxide into features formed on a workpiece containing a substrate, each of the features has sidewall surfaces, a bottom surface, and an aspect ratio of 20 or greater, wherein the deposition-etch cycle comprises:
conducting a plasma-enhanced atomic layer deposition (PE-ALD) process to deposit the silicon oxide on the sidewall surfaces and the bottom surfaces, wherein the PE-ALD process comprises applying a bias power to the workpiece and conducting an atomic layer deposition (ALD) cycle for at least 10 times to deposit the silicon oxide; and
conducting an etch process to selectively remove the silicon oxide from the sidewall surfaces while maintaining the silicon oxide on the bottom surfaces; and
repeating the deposition-etch cycle including the PE-ALD process and the etch process to bottom-up fill the features with the fill material.

2. The method of claim 1, wherein the deposition-etch cycle is performed in a range from 3 times to about 20 times.

3. The method of claim 1, wherein each of the ALD cycles comprises:
exposing the workpiece to a silicon precursor;
exposing the workpiece to a purge gas;
exposing the workpiece to an oxidizing plasma; and
exposing the workpiece to the purge gas;
wherein the workpiece is sequentially exposed to the silicon precursor, the purge gas, the oxidizing plasma, and the purge gas.

4. The method of claim 3, wherein the silicon precursor comprises: bis(diethylamino)silane, di(iso-propylamino)silane, bis(tert-butylamino)silane, di(sec-butylamino)silane, mono(disec-butylamino)silane, bis(diisopropylamino)disilane, bis(dimethylamino)dimethylsilane, tris(dimethylamino)silane, or any combination thereof, and wherein the silicon precursor is introduced at a flowrate within a range from about 10 milligram/minute (mgm) to about 500 mgm.

5. The method of claim 3, wherein the oxidizing plasma comprises atomic oxygen, oxygen gas (O₂), ozone, or any combination thereof, wherein the oxidizing plasma is formed from oxygen gas (O₂), and wherein the oxygen gas is introduced at a flowrate within a range from about 50 sccm to about 1,000 sccm.

6. The method of claim 3, wherein during the PE-ALD process, the workpiece and/or the processing region is heated or maintained at temperature in a range from about 300° C. to about 600° C., the processing region is maintained at a pressure in a range from about 0.1 Torr to about 10 Torr, and the oxidizing plasma has a power of about 50 watt to about 1,000 watt.

7. The method of claim 1, wherein the etch process is a wet etch process which comprises exposing the workpiece to an etch solution to selectively remove the silicon oxide from the sidewall surfaces while maintaining the silicon oxide on the bottom surfaces.

8. The method of claim 7, wherein the etch solution comprises hydrofluoric acid.

9. The method of claim 1, wherein the etch process is a dry etch process which comprises exposing the workpiece to a plasma etch to selectively remove the silicon oxide from the sidewall surfaces while maintaining the silicon oxide on the bottom surfaces, and wherein the dry etch process comprises generating a capacitively coupled plasma having a power of about 20 watt to about 200 watt.

10. The method of claim 9, wherein the dry etch process comprises exposing the workpiece to a plasma formed from a reactive gas comprising carbon tetrafluoride, nitrogen trifluoride, hydrogen fluoride, ammonia, or any combination thereof, and wherein the reactive gas is introduced at a flowrate within a range from about 10 sccm to about 500 sccm.

11. The method of claim 9, wherein the workpiece and/or the processing region is heated or maintained at temperature in a range from about 300° C. to about 600° C. during the dry etch process, and wherein the processing region is maintained at a pressure in a range from about 0.1 Torr to about 10 Torr during the dry etch process.

12. The method of claim 1, further comprising a feature layer disposed on the substrate, wherein the feature layer comprises the plurality of features formed therein, and wherein the feature layer comprises a silicon germanium film disposed on a silicon surface.

13. The method of claim 1, wherein the silicon oxide formed on the bottom surfaces of the features has a greater O:Si atomic ratio than the silicon oxide formed on the sidewall surfaces of the features; and/or wherein the silicon oxide formed on the sidewall surfaces of the features has a greater carbon concentration than the silicon oxide formed on the bottom surfaces of the features.

14. The method of claim 1, wherein the PE-ALD process further comprises exposing the workpiece to an oxidizing plasma to form the silicon oxide, and wherein the bottom surfaces of the features are exposed to a greater concentration of the oxidizing plasma than the sidewall surfaces of the features.

15. The method of claim 14, wherein the oxidizing plasma has a flow path which is perpendicular or substantially perpendicular relative an upper surface of the workpiece.

16. A method, comprising:
conducting a deposition-etch cycle to deposit a fill material comprising silicon oxide into features formed on a workpiece containing a substrate, each of the features has sidewall surfaces and a bottom surface, and wherein the deposition-etch cycle comprises:
conducting a plasma-enhanced atomic layer deposition (PE-ALD) process to deposit the silicon oxide on the sidewall surfaces and the bottom surfaces, wherein the PE-ALD process comprises applying a bias power to the workpiece and conducting an atomic layer deposition (ALD) cycle to deposit the silicon oxide, and wherein each of the ALD cycles comprises:
exposing the workpiece to a silicon precursor;
exposing the workpiece to a purge gas;
exposing the workpiece to an oxidizing plasma; and
exposing the workpiece to the purge gas;
wherein the workpiece is sequentially exposed to the silicon precursor, the purge gas, the oxidizing plasma, and the purge gas; and
conducting an etch process to selectively remove the silicon oxide from the sidewall surfaces while maintaining the silicon oxide on the bottom surfaces, wherein the etch process is a wet etch process which comprises exposing the workpiece to an etch solution to selectively remove the silicon oxide from the sidewall surfaces while maintaining the silicon oxide on the bottom surfaces; and
repeating the deposition-etch cycle including the PE-ALD process and the etch process to bottom-up fill the features with the fill material.

17. The method of claim 16, wherein the etch solution comprises hydrofluoric acid.

18. A method, comprising:
conducting a deposition-etch cycle to deposit a fill material comprising silicon oxide into features formed on a workpiece containing a substrate, each of the features has sidewall surfaces and a bottom surface, and wherein the deposition-etch cycle comprises:
conducting a plasma-enhanced atomic layer deposition (PE-ALD) process to deposit the silicon oxide on the sidewall surfaces and the bottom surfaces, wherein the PE-ALD process comprises applying a bias power to the workpiece and conducting an atomic layer deposition (ALD) cycle to deposit the silicon oxide, and wherein each of the ALD cycles comprises:
exposing the workpiece to a silicon precursor;
exposing the workpiece to a purge gas;
exposing the workpiece to an oxidizing plasma; and
exposing the workpiece to the purge gas;
wherein the workpiece is sequentially exposed to the silicon precursor, the purge gas, the oxidizing plasma, and the purge gas; and
conducting an etch process to selectively remove the silicon oxide from the sidewall surfaces while maintaining the silicon oxide on the bottom surfaces, wherein the etch process is a dry etch process which comprises exposing the workpiece to a plasma etch to selectively remove the silicon oxide from the sidewall surfaces while maintaining the silicon oxide on the bottom surfaces; and
repeating the deposition-etch cycle including the PE-ALD process and the etch process to bottom-up fill the features with the fill material.

19. The method of claim 18, wherein the dry etch process comprises generating a capacitively coupled plasma having a power of about 20 watt to about 200 watt.

20. The method of claim 18, wherein the dry etch process comprises exposing the workpiece to a plasma formed from a reactive gas comprising carbon tetrafluoride, nitrogen trifluoride, hydrogen fluoride, ammonia, or any combination thereof.
